(19) United States
(12) Patent Application Publication
(10) Pub. No.: US 2012/0299574 A1
(43) Pub. Date: Nov. 29, 2012

(54) CALIBRATION APPARATUS FOR PROBES

(75) Inventors: CHUANG-WEI TSENG, Tu-Cheng (TW); CHI-MIN WANG, Tu-Cheng (TW); CHIH-YU YEH, Tu-Cheng (TW); CHIA-MING YEH, Tu-Cheng (TW)

(73) Assignee: HON HAI PRECISION INDUSTRY CO., LTD., Tu-Cheng (TW)

(21) Appl. No.: 13/171,460

(22) Filed: Jun. 29, 2011

(30) Foreign Application Priority Data
May 23, 2011 (TW) 100118034

(51) Int. Cl. G01R 35/04

(52) U.S. Cl. 324/74

(57) ABSTRACT

An apparatus includes a connector and a connecting apparatus. The connector includes a first pin and a shell surrounding the first pin. The shell is insulated from the first pin. The connecting apparatus includes a main body, a second pin, and a third pin. The main body is connected to a bottom of the shell of the connector. First ends of the second and third pins extend through the main body, to be electrically connected to the first pin and the shell, respectively. Second ends of the second and third pins are exposed through a bottom of the main body.

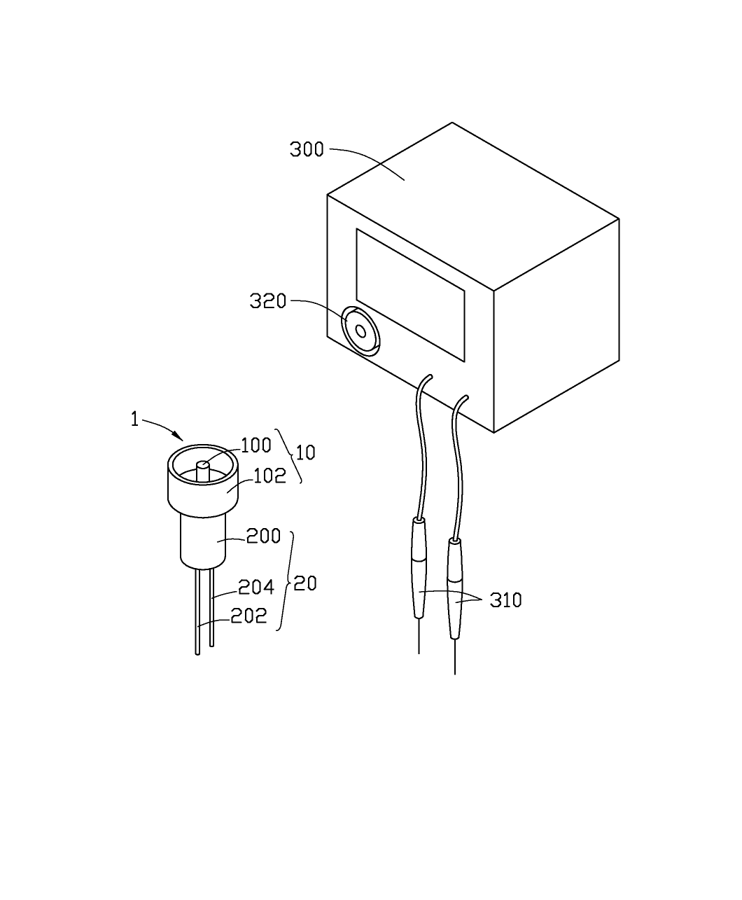

### BACKGROUND

1. Technical Field

The present disclosure relates to an apparatus for calibrating probes.

2. Description of Related Art

Some properties of electronic products need to be tested with oscilloscopes. The probes of an oscilloscope need to be calibrated before being used. In general, two probes of the oscilloscope can be calibrated manually by electrically connecting the two probes of the oscilloscope. Namely, the first ends of the two poles are respectively connected to the two probes of the oscilloscope, and second ends of the two poles are respectively connected to a bayonet nut connector (BNC) and a shell of the oscilloscope for calibration. However, this is inconvenient and may cause an inaccurate calibration. Therefore, there is room for improvement in the art.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the several views.

The FIGURE is a schematic diagram of an apparatus for correcting probes in accordance with an exemplary embodiment of the present disclosure.

### DETAILED DESCRIPTION

The disclosure, including the drawing, is illustrated by way of example and not by limitation. References to “an” or “one” embodiment in this disclosure are not necessarily to the same embodiment, and such references mean at least one.

Referring to the drawing, an apparatus 1 is used for calibrating probes 310 of an oscilloscope 300. The apparatus 1 in accordance with an exemplary embodiment includes a bayonet nut connector (BNC) 10 and a connecting apparatus 20 extending from a bottom of the BNC 10.

In one embodiment, the BNC 10 is a male BNC. The BNC 10 includes a pin 100 and a shell 102 surrounding the pin 100. The pin 100 is insulated from the shell 102.

The connecting apparatus 20 includes a main body 200 connected to a bottom of the shell 102, and pins 202 and 204. The main body 200 is a heat-shrinkable tube. First ends of the pins 202 and 204 extend through the main body 200, to be electrically connected to the pin 100 and the shell 102, respectively. The second ends of the pins 202 and 204 extend out of a bottom of the main body 200.

In use, the BNC 10 is connected to a female BNC 320 of the oscilloscope 300. The pins 202 and 204 are respectively connected to the two probes 310 of the oscilloscope 300, to gain data from the two probes 310 of the oscilloscope 300 and send the data to the oscilloscope 300 through the connecting apparatus 20 and the BNC 10. The oscilloscope 300 analyzes and displays the data for calibrating the probes 310 of the oscilloscope 300.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. An apparatus for calibrating two probes of an oscilloscope, the apparatus comprising:
a first connector to be connected to a second connector of the oscilloscope, the first connector comprising a first pin and a shell surrounding the first pin, wherein the shell is insulated from the first pin; and
a connecting apparatus comprising a main body, a second pin, and a third pin, wherein the main body is connected to a bottom of the shell of the first connector, first ends of the second and third pins extend through the main body, to be electrically connected to the first pin and the shell, respectively, second ends of the second and third pins are exposed through a bottom of the main body, to be electrically connected to the probes of the oscilloscope.

2. The apparatus of claim 1, wherein the main body is a heat-shrinkable tube.

3. The apparatus of claim 1, wherein the first connector is a male bayonet nut connector.
